(19) United States
(12) Patent Application Publication
(10) Pub. No.: US 2014/0015118 A1
(43) Pub. Date: Jan. 16, 2014

(54) SEMICONDUCTOR CHIP INCLUDING HEAT RADIATION PORTION AND METHOD OF FABRICATING THE SEMICONDUCTOR CHIP

(71) Applicant: SAMSUNG ELECTRONICS CO., LTD., Suwon-si (KR)

(72) Inventors: Jong-kon BAE, Seoul (KR); Jae-hyuck WOO, Osan-si (KR); Won-sik KANG, Seoul (KR); Sung-ki KIM, Seoul (KR); Yang-hyo KIM, Hwaseong-si (KR)

(73) Assignee: SAMSUNG ELECTRONICS CO., LTD., Suwon-Si (KR)

(21) Appl. No.: 13/834,091

(22) Filed: Mar. 15, 2013

(30) Foreign Application Priority Data
Jul. 12, 2012 (KR) 10-2012-0076283

(51) Int. Cl. H01L 23/367

(52) U.S. Cl. CPC H01L 23/3675
USPC 257/713

(57) ABSTRACT

A semiconductor chip includes a semiconductor substrate including a first surface and a second surface, an integrated circuit (IC) on the first surface of the semiconductor substrate, and a heat radiation portion on the second surface of the semiconductor substrate. The heat radiation portion includes heat radiation patterns in a direction perpendicular to the second surface, and a heat radiation layer on upper portions of the heat radiation patterns. The heat radiation patterns include a plurality of recesses and a plurality of protrusions and the heat radiation layer includes a metal material and has a flat upper surface.

### CROSS-REFERENCE TO RELATED APPLICATIONS

This application claims the benefit of Korean Patent Application No. 10-2012-0076283, filed on Jul. 12, 2012, in the Korean Intellectual Property Office, the disclosure of which is incorporated herein in its entirety by reference.

### BACKGROUND

1. Field

Some example embodiments relate to a semiconductor chip and a method of fabricating the semiconductor chip, for example, to a semiconductor chip including a heat radiation portion on one surface of the semiconductor chip.

2. Description of the Related Art

As electronic products are required to provide various functions at high speed, the processing speed of circuits integrated in semiconductor chips mounted on electronic products has increased. However, the power consumption of semiconductor chips has also increased. In addition, as the size and resolution of display modules mounted in mobile electronic devices, such as smartphones, have increased, the power consumption of display driving chips has greatly increased. Accordingly, as the semiconductor chips generate more heat, the heat radiation of the semiconductor chips has also increased. Thus, the semiconductor chips are required to effectively dissipate heat generated to the external environment when the circuits integrated in the semiconductor chips operate.

### SUMMARY

Some example embodiments provide a semiconductor chip that includes a heat radiation portion on one surface thereof to dissipate heat generated therein to the outside.

According to an example embodiment, a semiconductor chip includes a semiconductor substrate including a first surface and a second surface, an integrated circuit (IC) on the first surface of the semiconductor substrate, and a heat radiation portion on the second surface of the semiconductor substrate. The heat radiation portion includes heat radiation patterns in a direction perpendicular to the second surface, and a heat radiation layer on upper portions of the heat radiation patterns. The heat radiation patterns include a plurality of recesses and a plurality of protrusions, and the heat radiation layer includes a metal material and has a flat upper surface.

The heat radiation layer may include burying portions in the plurality of recesses, and the burying portions may include the metal material. The heat radiation layer may include burying portions in the plurality of recesses, the burying portions including the metal material, and an exposure portion on an upper portion of each of the burying portions and an upper portion of each of the plurality of protrusions.

The heat radiation patterns may include stripe patterns on the second surface, the stripe patterns including the plurality of protrusions having straight line shapes extending in a first direction, the plurality of protrusions being formed along a second direction perpendicular to the first direction and spaced apart from one another. The heat radiation patterns may include lattice patterns on the second surface, the lattice patterns including one of the plurality of protrusions and the plurality of recesses having rectangular shapes formed in a first direction and in a second direction perpendicular to the first direction and spaced apart from one another.

The heat radiation patterns may include circular patterns on the second surface, the circular patterns including one of the plurality of protrusions and the plurality of recesses having circular shapes formed in a first direction and in a second direction perpendicular to the first direction and spaced apart from one another. The heat radiation patterns may include ring-shaped patterns on the second surface, the ring-shaped patterns including one of the plurality of protrusions and the plurality of recesses having ring shapes formed in a first direction and in a second direction perpendicular to the first direction and spaced apart from one another.

One of a top end of a longitudinal cross-section of each of the plurality of protrusions and a bottom end of a longitudinal cross-section of each of the plurality of recesses is one of straight and round. Each of the plurality of recesses may have one of an inverted triangular cross-section and an inverted trapezoidal cross-section. The metal material may include a silicon compound including one of carbon and silver. The IC may include a driving circuit configured to drive a display panel.

According to an example embodiment, a method of fabricating a semiconductor chip includes forming a circuit region in a first surface of a semiconductor substrate, backwrapping a second surface of the semiconductor substrate facing the first surface, forming heat radiation patterns by generating a plurality of recesses and a plurality of protrusions on the second surface, forming a heat radiation layer by applying a metal material onto upper portions of the heat radiation patterns, and planarizing a top surface of the heat radiation layer.

The heat radiation patterns may be formed on an entire area of the second surface. The heat radiation patterns may be formed by performing a photolithography process at a temperature less than 100° C.

According to an example embodiment, a semiconductor chip includes a semiconductor substrate including a first surface and a second surface, an integrated circuit (IC) on the first surface of the semiconductor substrate, and a heat radiation portion on the second surface of the semiconductor substrate. The heat radiation portion includes a plurality of recesses and a metal material in the plurality of recesses.

The heat radiation portion may have a flat upper surface. The heat radiation portion may further include a plurality of protrusions separated by the plurality of recesses. One of a top end of a longitudinal cross-section of each of the plurality of protrusions and a bottom end of a longitudinal cross-section of each of the plurality of recesses may be one of straight and round. The plurality of protrusions may have straight line shapes extending in a first direction and formed along a second direction perpendicular to the first direction. At least one of the plurality of protrusions and the plurality of recesses may have one of circular, ring and rectangular shapes formed in a first direction and in a second direction perpendicular to the first direction. Each of the plurality of recesses may have one of an inverted triangular cross-section and an inverted trapezoidal cross-section. The metal material may include a silicon compound including one of carbon and silver.

### BRIEF DESCRIPTION OF THE DRAWINGS

Example embodiments of the inventive concepts will be more clearly understood from the following detailed description taken in conjunction with the accompanying drawings in which:

FIG. 1 is a longitudinal cross-sectional view of a semiconductor chip according to an example embodiment;

FIGS. 2A through 2C are perspective views of a heat radiation portion of the semiconductor chip illustrated in FIG. 1;

FIGS. 3A through 3M are plan views of heat radiation patterns of the heat radiation portion of FIG. 1;

FIGS. 4A through 4I are longitudinal cross-sectional views of the heat radiation portion of FIG. 1;

FIG. 5 is a longitudinal cross-sectional view of a semiconductor chip according to another example embodiment;

FIGS. 6A through 6I are longitudinal cross-sectional views of a heat radiation portion of the semiconductor chip illustrated in FIG. 5;

FIGS. 7A through 7E and FIG. 8 illustrate a method of fabricating a semiconductor chip according to an example embodiment;

FIG. 9 is a longitudinal cross-sectional view of a semiconductor chip according to another example embodiment;

FIG. 10 is a longitudinal cross-sectional view of a display module on which a display driving chip is mounted, according to an example embodiment;

FIG. 11 is a plan view of a display module according to another example embodiment;

FIG. 12 illustrates a structure of a display device according to an example embodiment; and

FIG. 13 illustrates examples of various electronic products including a display device, according to an example embodiment.

### DETAILED DESCRIPTION

As used herein, the term “and/or” includes any and all combinations of one or more of the associated listed items.

The attached drawings for illustrating example embodiments are referred to in order to gain a sufficient understanding of the inventive concepts, the merits thereof, and the objectives accomplished by the implementation of the inventive concepts. The inventive concepts may, however, be embodied in many different forms and should not be construed as being limited to the embodiments set forth herein; rather, these embodiments are provided so that this disclosure will be thorough and complete, and will fully convey the inventive concepts to those skilled in the art. Like reference numerals refer to like elements. The sizes of structures in the attached drawings are enlarged or reduced compared to actual sizes for clarity of the inventive concepts.

The terminology used herein is for the purpose of describing particular embodiments only and is not intended to be limiting of the inventive concepts. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

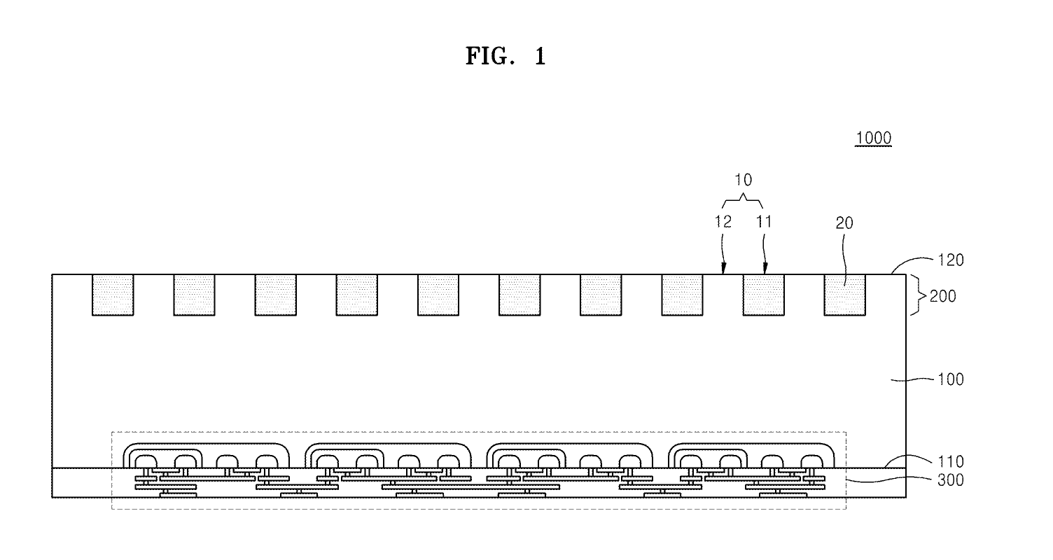

FIG. 1 is a longitudinal cross-sectional view of a semiconductor chip 1000 according to an example embodiment. Referring to FIG. 1, the semiconductor chip 1000 according to the example embodiment includes an integrated circuit (IC) 300 formed on a first surface 110 of a semiconductor substrate 100 and a heat radiation portion 200 formed on a second surface 120 of the semiconductor substrate 100 that faces the first surface 110.

The semiconductor substrate 100 may be a semiconductor wafer including the first surface 110 and the second surface 120 that faces the first surface 110. The semiconductor substrate 100 may include silicon (Si). In addition, the semiconductor substrate 100 may include a semiconductor element, such as germanium (Ge), or a compound semiconductor, such as silicon carbide (SiC), gallium arsenide (GaAs), indium arsenide (InAs), and indium phosphide (InP).

The IC 300 is formed on the first surface 110 of the semiconductor substrate 100. The IC 300 is configured of wirings that apply voltages to semiconductor devices, such as transistors, capacitors and/or diodes, and the like or electrically connect the semiconductor devices.

The IC 300 may be of various types. For example, when the semiconductor chip 1000 is a display driving chip, the IC 300 may be a circuit that generates driving signals for driving a display panel. In addition, when the semiconductor chip 1000 is a memory chip, the IC 300 may be a circuit that includes memory cells and their peripheral circuits. In addition, the IC 300 may include various types of circuits that perform functions according to types of semiconductor chips.

The heat radiation portion 200 may include heat radiation patterns 10 and a heat radiation layer 20 that are formed on the whole of the second surface 120 of the semiconductor substrate 100. The heat radiation patterns 10 have a heat radiation structure including a recess 11 and a protrusion 12. A plurality of recesses 11 are formed on the second surface 120 of the semiconductor substrate 100, and the plurality of recesses 11 are spaced apart from one another by given (or alternatively, predetermined) distances so that a plurality of protrusions 12 may be formed. Thus, the heat radiation patterns 10 including the plurality of recesses 11 and the plurality of protrusions 12 may be formed.

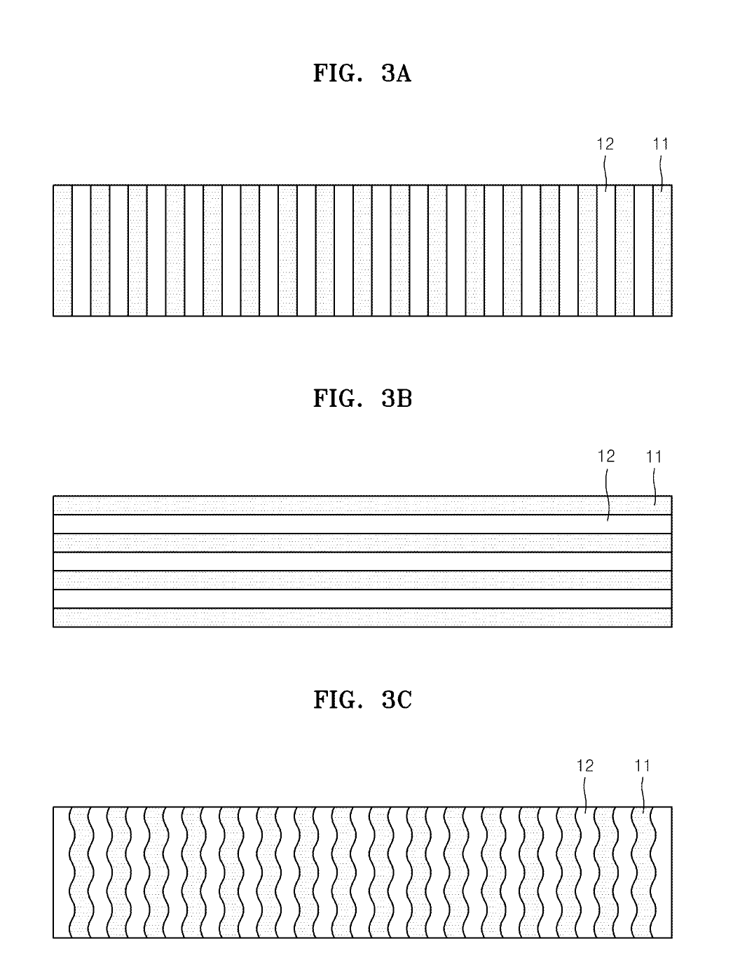

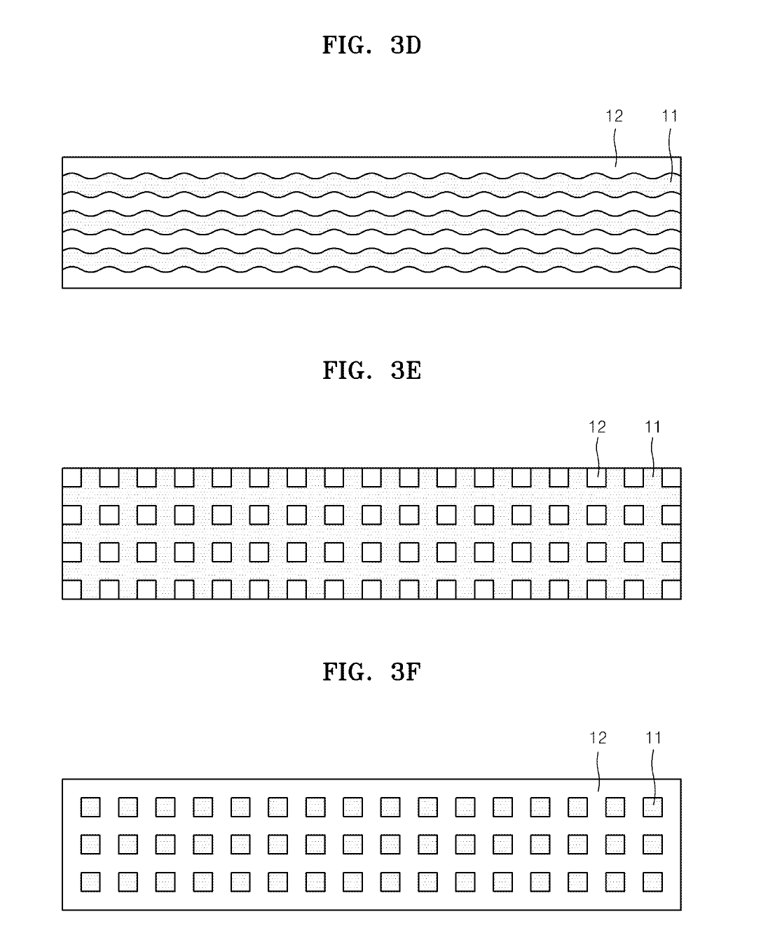

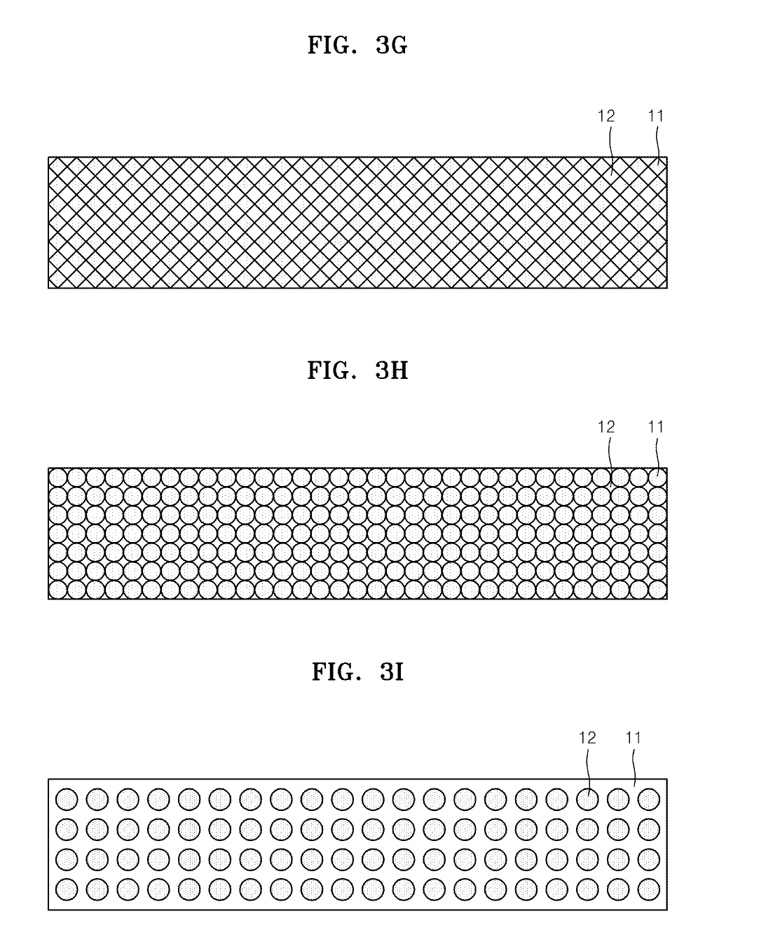

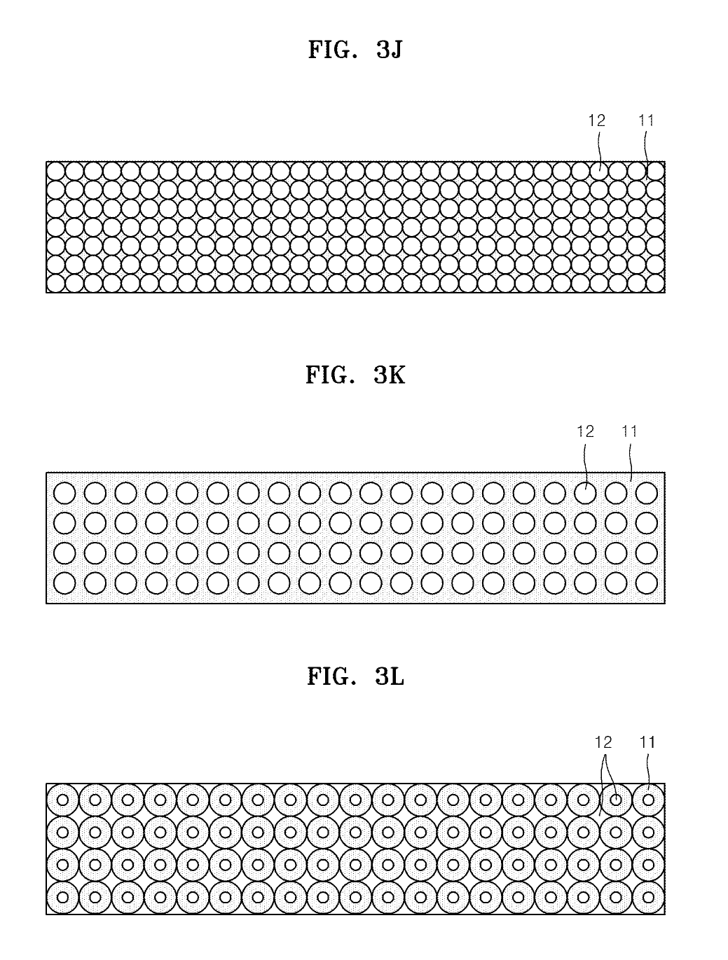

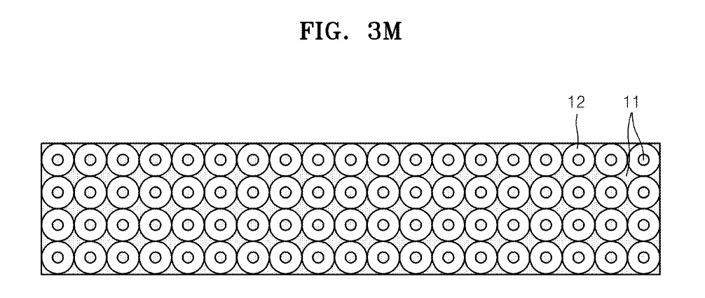

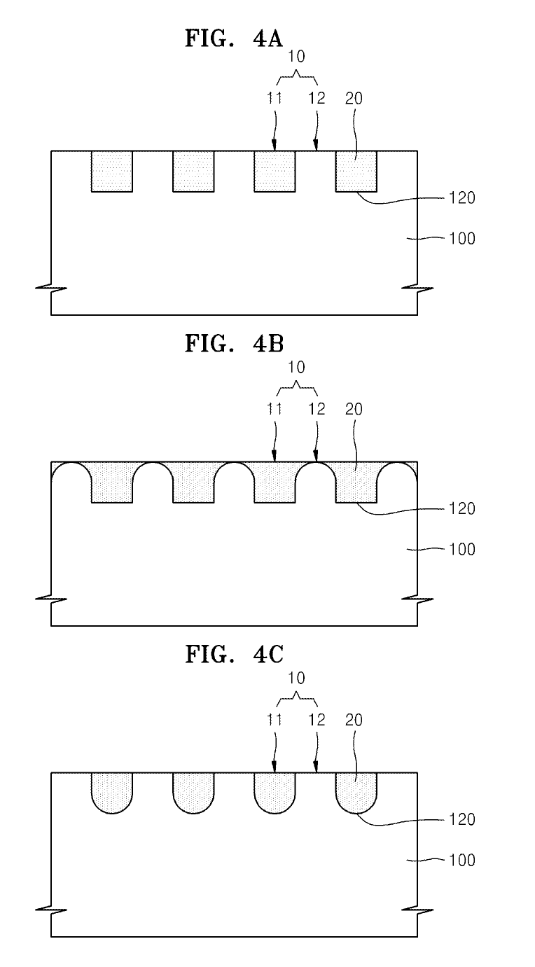

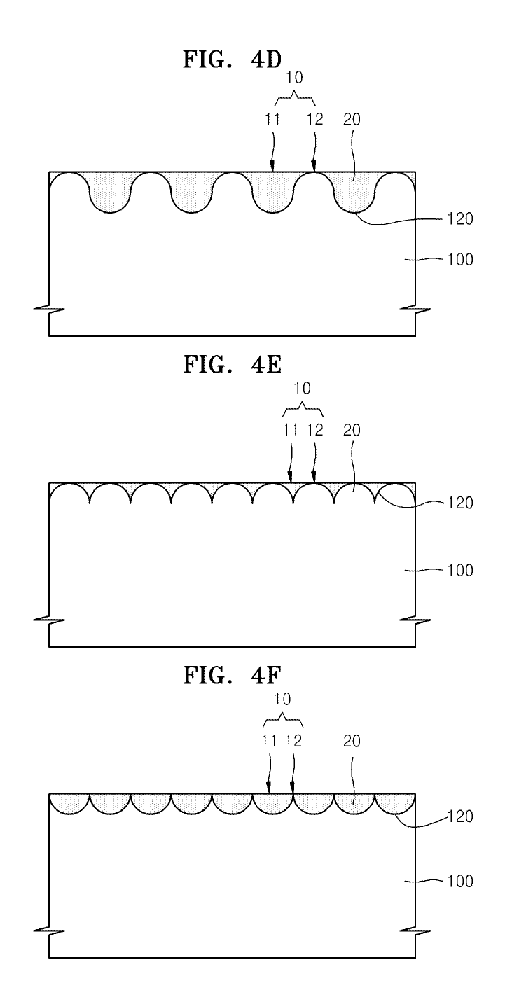

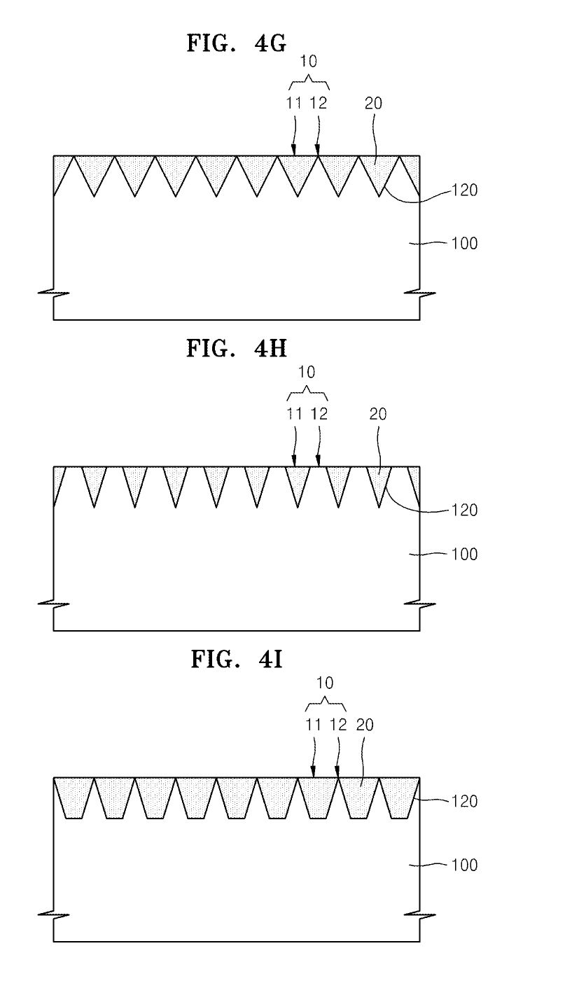

The shape of the heat radiation patterns 10 is not limited as long as a heat radiation area may be increased. The heat radiation patterns 10 may be stripe patterns (FIGS. 3A-3B), lattice patterns (FIGS. 3E-3G), or circular patterns (FIGS. 3H-3M), as illustrated in FIGS. 3A through 3M. In addition, in the present embodiment, a bottom end of each recess 11 and a top end of each protrusion 10 have straight line-shaped cross-sections; however, this is just an example, and the inventive concepts are not limited thereto. The shape of the cross-section of the recess 11 and the shape of the cross-section of the protrusion 12 may vary, as illustrated in FIGS. 4A through 4I.

The heat radiation layer 20 may be formed on upper portions of the heat radiation patterns 10. The heat radiation layer 20 may be formed by burying a heat radiation material, that is, a metal, in the recesses 11. In this case, the heat radiation material may be a material having higher thermal conductivity, such as carbon or silver. Alternatively, the heat radiation material may be a silicon compound that is mixed with carbon or silver. The heat radiation layer 20 is formed by burying the material having higher thermal conductivity in the recesses 11 so that heat generated in the semiconductor chip 1000 may be dissipated to the external environment at a relatively high speed. In addition, the silicon compound is applied onto the second surface 120 of the semiconductor substrate 100 so that cracks may be prevented or inhibited from occurring in the semiconductor chip 100.

The thickness of the heat radiation layer 20 may be the same as the thickness of the heat radiation patterns 10. The heat radiation material is buried in a boundary between longitudinal sections of the protrusions 12 so that the thickness of the heat radiation layer 20 may be the same as the thickness of the heat radiation patterns 10. In addition, a top surface of the heat radiation portion 200 may be flat.

The heat radiation portion 200 may be generated after a backwrap process of the semiconductor wafer is performed. The semiconductor chip 1000 is formed on a wafer-based semiconductor substrate having a thickness of several hundreds of μm, and the thickness of the semiconductor chip is to be reduced to be less than maximum several tens of μm so as to stack the semiconductor chip 1000 or to increase a packaging density. A process of polishing a rear surface of a wafer after circuits of the semiconductor chip are formed on the wafer, so as to reduce the thickness of the semiconductor chip, is referred to as a backwrap process. Referring to FIG. 1, after the IC 300 has been formed on the first surface 110 of the semiconductor substrate 100, a portion of the second surface 120 of the semiconductor substrate 100 is polished by performing the backwrap process. Subsequently, the heat radiation portion 200 may be formed on the second surface 120 of the semiconductor substrate 100.

Indirect methods, such as a method of reducing the level of a power supply voltage applied to the semiconductor chip so as to reduce consumed power of the semiconductor chip, or in case of a display module, a method of attaching a heat diffusion sheet to a rear surface of the display module so as to dissipate heat generated in the semiconductor chip to the external environment, are used to solve problems relating to heat radiation of the semiconductor chip. However, the semiconductor chip 1000 illustrated in FIG. 1 may dissipate heat generated by an operation of the IC 300 directly to the outside via the heat radiation portion 200 formed on the second surface 120 of the semiconductor substrate 100. In addition, the heat radiation portion 200 is formed on the second surface 120 that faces the first surface 110 of the semiconductor substrate 100 on which the IC 300 is formed. Thus, the heat radiation portion 200 may have a relatively large area without the need of increasing the size of the semiconductor chip 1000.

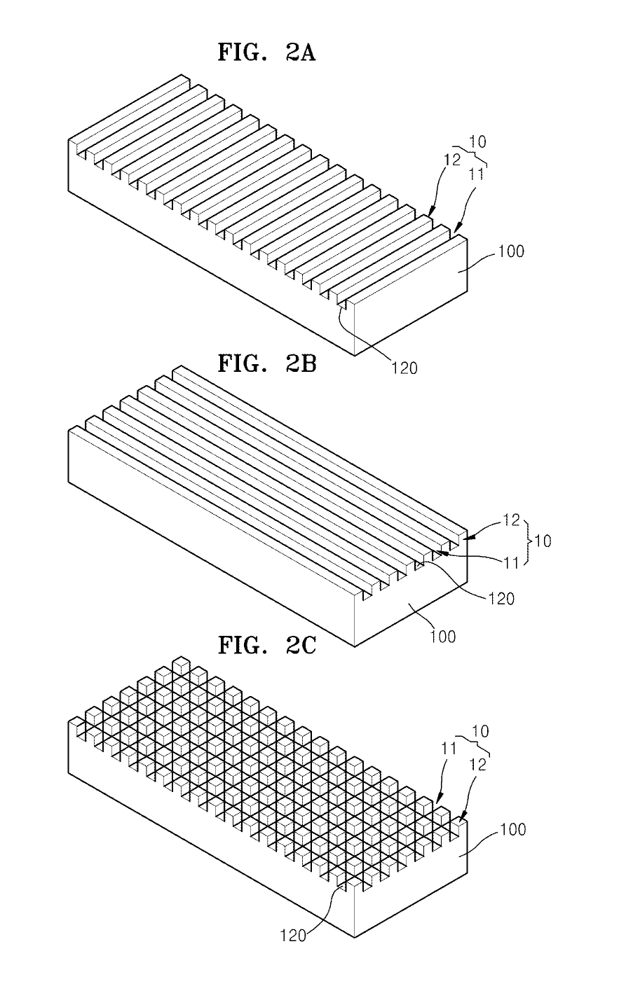

FIGS. 2A through 2C are schematic perspective views of the semiconductor chip 1000 of FIG. 1 so as to illustrate the structure of the heat radiation patterns 10 of the heat radiation portion 200, according to other example embodiments. For convenience of explanation, the heat radiation layer 20 is not shown. In the example embodiment, the semiconductor chip 1000 has a shape of a rectangle with a length of the long side much larger than a length of the short side, like a display driving chip. However, the inventive concepts are not limited thereto. The semiconductor chip 1000 illustrated in FIG. 1 may have various shapes. In addition, the semiconductor chip 1000 of FIG. 1 may include various types of circuits, such as a memory, an analog circuit, a logic circuit, and the like.

Referring to FIGS. 2A through 2C, a plurality of grooves (not shown) are formed in the second surface 120 of the semiconductor substrate 100 in a direction that is perpendicular to or parallel to the longer side of the semiconductor chip 1000 so that the heat radiation patterns 10 including the plurality of recesses 11 and the plurality of protrusions 12 may be formed. The plurality of recesses 11 may be spaced apart from one another by given (or alternatively, predetermined) distances, and distances between the plurality of recesses 11 may be uniform. The plurality of protrusions 12 are disposed between the plurality of recesses 11. The plurality of protrusions 12 are also spaced apart from one another by given (or alternatively, predetermined) distances.

In one example embodiment, the thickness of the recess 11 and the thickness of the protrusion 12 may be the same. The heat radiation patterns 10 formed by the plurality of recesses 11 and the plurality of protrusions 12 may be stripe patterns that are disposed in a direction perpendicular to the longer side of the semiconductor chip 1000, as illustrated in FIG. 2A, or may be stripe patterns that are disposed in a direction parallel to the longer side of the semiconductor chip 1000, as illustrated in FIG. 2B. In addition, the heat radiation patterns 10 may be lattice patterns that are formed when the plurality of recesses 11 formed in the direction perpendicular to the longer side of the semiconductor chip 1000 and the plurality of protrusions 12 formed in the direction parallel to the long side of the semiconductor chip 1000 cross one another, as illustrated in FIG. 2C. However, FIGS. 2A through 2C are just embodiments for illustrating the heat radiation patterns 10 of the heat radiation portion 200, and the inventive concepts are not limited thereto. The shape of the heat radiation patterns 10 and the shapes of the recesses 11 and the protrusions 12 that constitute the heat radiation patterns 10 may vary. Hereinafter, the heat radiation patterns 10 will be described in greater detail with reference to FIGS. 3A through 3M and FIGS. 4A through 4I.

FIGS. 3A through 3M are plan views of the heat radiation patterns 10 of the heat radiation portion 200 of FIG. 1. As described above in FIG. 1, the heat radiation portion 200 may be formed on the whole of the second surface 120 of a semiconductor substrate (see 100 of FIG. 1). The heat radiation patterns 10 may be formed as illustrated in FIGS. 3A through 3M, depending on various shapes and arrangements of the recesses 11 and the protrusions 12 of the heat radiation portion 200.

First, referring to FIGS. 3A and 3B, the heat radiation patterns 10 of the heat radiation portion 200 may be straight stripe patterns. Referring to FIG. 3A, a recess 11 may have a straight line shape extending in a first direction, for example, in a direction that is perpendicular to a longer side of a semiconductor chip (see 1000 of FIG. 1) (hereinafter referred to as a first direction), and a plurality of recesses 11 may be formed spaced apart from one another by given (or alternatively, predetermined) distances. Thus, the heat radiation patterns 10 may be straight stripe patterns in which the plurality of recesses 11 extend in the first direction.

In addition, referring to FIG. 3B, a recess 11 may have a straight line shape extending in a second direction, for example, in a direction that is parallel to the longer sides of the semiconductor chip (see 1000 of FIG. 1) (hereinafter referred to as a second direction), and a plurality of recesses 11 may be formed spaced apart from one another by given (or alternatively, predetermined) distances. Thus, the heat radiation patterns 10 may be straight stripe patterns in which the plurality of recesses 11 extend in the second direction.

Referring to FIGS. 3C and 3D, the heat radiation patterns 10 may be wave stripe patterns. Referring to FIG. 3C, a recess 11 may have a wave stripe shape in which the recess 11 extends in the first direction, and a plurality of recesses 11 may be formed spaced apart from one another by given (or alternatively, predetermined) distances. Thus, the heat radiation patterns 10 may be wave stripe patterns in which the plurality of recesses 11 extend in the first direction.

In addition, referring to FIG. 3D, a recess 11 may have a wave stripe shape in which the recess 11 extends in the second direction, and a plurality of recesses 11 may be formed spaced apart from one another by given (or alternatively, predetermined) distances. Thus, the heat radiation patterns 10 may be wave stripe patterns in which the plurality of recesses 11 extend in the second direction.

Referring to FIGS. 3E and 3F, the heat radiation patterns 10 of the heat radiation portion 200 may be lattice patterns. Referring to FIG. 3E, a recess 11 may have a straight line shape in which the recess 11 extends in the first direction and the second direction, respectively, and a plurality of recesses 11 may be disposed spaced apart from one another by given (or alternatively, predetermined) distances. Thus, the heat radiation patterns 10 may be lattice patterns in which the plurality of recesses 11 in the first direction and the plurality of recesses 11 in the second direction cross one another.

In addition, referring to FIG. 3F, contrary to FIG. 3E, a protrusion 12 may have a straight line shape in which the protrusion 12 extends in the first direction and in the second direction, respectively, and a plurality of protrusions 12 may be disposed spaced apart from one another by given (or alternatively, predetermined) distances. Thus, the heat radiation patterns 10 may be lattice patterns in which the plurality of protrusions 12 in the first direction and the plurality of protrusions 12 in the second direction cross one another.

Referring to FIG. 3G, the heat radiation patterns 10 may be diamond patterns. Each of a recess 11 and a protrusion 12 may have a diamond shape, and a plurality of recesses 11 and a plurality of protrusions 12 may be alternately disposed along a third direction, for example, in a direction of a slant line with respect to the longer side of a semiconductor chip (see 1000 of FIG. 1) (hereinafter referred to as a third direction). Thus, the heat radiation patterns 10 may be diamond patterns, as illustrated in FIG. 3G.

Referring to FIGS. 3H and 3K, the heat radiation patterns 10 may be circular patterns. As illustrated in FIGS. 3H and 3I, a recess 11 may have a circular shape, and a plurality of recesses 11 may be disposed along the first direction and along the second direction (FIG. 3H) or may be spaced apart from one another by given (or alternatively, predetermined) distances in the first direction and in the second direction (FIG. 3I). Alternatively, as illustrated in FIGS. 3J and 3K, a protrusion 12 may have a circular shape, and a plurality of protrusions 12 may be disposed along the first direction and along the second direction (FIG. 3J) or may be spaced apart from one another by given (or alternatively, predetermined) distances in the first direction and in the second direction (FIG. 3K). Thus, the heat radiation patterns 10 may be circular patterns.

Referring to FIGS. 3L and 3M, the heat radiation patterns 10 may be ring-shaped patterns. Referring to FIG. 3L, a recess 11 may have a ring shape, and a plurality of recesses 11 may be disposed along the first direction and along the second direction. Alternatively, referring to FIG. 3M, a protrusion 12 may have a ring shape, and a plurality of protrusions 12 may be disposed along the first direction and along the second direction. Thus, the heat radiation patterns 10 may be ring-shaped patterns.

As described above, various examples of the heat radiation patterns 10 of the heat radiation portion 200 have been described with reference to FIGS. 3A through 3M. However, the inventive concepts are not limited thereto. The heat radiation portion 200 may have heat radiation patterns 10 having various shapes in consideration of a heat radiation area and heat radiation efficiency.

FIGS. 4A through 4I are longitudinal cross-sectional views of the heat radiation portion 200 of FIG. 1. In order to explain a longitudinal cross-section of the heat radiation portion 200 of FIG. 1, FIGS. 4A through 4I are schematic longitudinal cross-sectional views of the semiconductor chip 1000 of FIG. 1. For convenience of explanation, the longitudinal cross-section of the semiconductor chip 1000 of FIG. 1 including the heat radiation portion 200 is enlarged.

Referring to FIG. 4A, a bottom end of a cross-section of the recess 11 of the heat radiation portion 200 and top end of a cross-section of the protrusion 12 of the heat radiation 200 may be straight. A plurality of recesses 11 or a plurality of protrusions 12 are spaced apart from one another by given (or alternatively, predetermined) distances so that the recesses 11 and the protrusions 12 may be alternately disposed. Thus, as illustrated in FIG. 4A, the cross-section of the recess 11 and the cross-section of the protrusion 12 may be rectangular, and the cross-section of the heat radiation layer 20 formed by burying a heat radiation material in the recess 11 may be rectangular like the cross-section of the recess 11. In the following patterns, the cross-section of the heat radiation layer 20 has the same shape as that of the recess 11. Thus, descriptions of the heat radiation layer 20 will be omitted.

Referring to FIG. 4B, a bottom end of the cross-section of the recess 11 of the heat radiation portion 200 may be straight, and a top end of the cross-section of the protrusion 12 may be round. The recesses 11 and the protrusions 12 may be alternately disposed. Thus, the cross-section of the protrusion 12 may have a pillar shape including a convex region in an upward direction.

Referring to FIG. 4C, contrary to FIG. 4B, the bottom end of the cross-section of the recess 11 may be round, and the top end of the cross-section of the protrusion 12 may be straight. Thus, the cross-section of the recess 11 may have a pillar shape including a convex region in a downward direction.

Referring to FIG. 4D, the bottom end of the cross-section of the recess 11 and the bottom end of the cross-section of the protrusion 12 may be round. Thus, as illustrated in FIG. 4D, the cross-section of the heat radiation pattern 10 including the recess 11 and the protrusion 12 may have a wave stripe shape.

Referring to FIG. 4E, the top end of the cross-section of the protrusion 12 and may be straight, and a plurality of protrusions 12 may be formed. Thus, the cross-section of the protrusion 12 may have a semicircular shape that is convex in an upward direction.

Referring to FIG. 4F, contrary to FIG. 4E, the bottom end of the cross-section of the recess 11 may be round, and a plurality of recesses 11 may be formed. Thus, the cross-section of the recess 11 may have a semicircular shape that is convex in a downward direction.

Referring to FIG. 4G, the recess 11 may have an inverted triangular cross-section, and the protrusion 12 may have a rectangular cross-section. Thus, the heat radiation pattern 10 including the recess 11 and the protrusion 12 may have a saw-toothed cross-section.

Referring to FIG. 4H, the recess 11 may have an inverted triangular cross-section, and the protrusion 12 may have a trapezoidal shape. The recesses 11 each having an inverted triangular cross-section may be spaced apart from one another by given (or alternatively, predetermined) distances so that the protrusion 12 may have a trapezoidal cross-section.

Alternatively, as illustrated in FIG. 4I, the recess 11 may have an inverted trapezoidal cross-section, and the protrusion 12 may have a triangular cross-section. The protrusions 12 each having a triangular cross-section may be spaced apart from one another by given (or alternatively, predetermined) distances so that the recess 11 may have an inverted trapezoidal cross-section.

As described above, various examples of the cross-section of the recess 11 and the cross-section of the protrusion 12 have been described. However, the inventive concepts are not limited thereto. The shape of the cross-section of the recess 11 and the shape of the cross-section of the protrusion 12 are not limited as long as the area of the heat radiation patterns 10 may be increased.

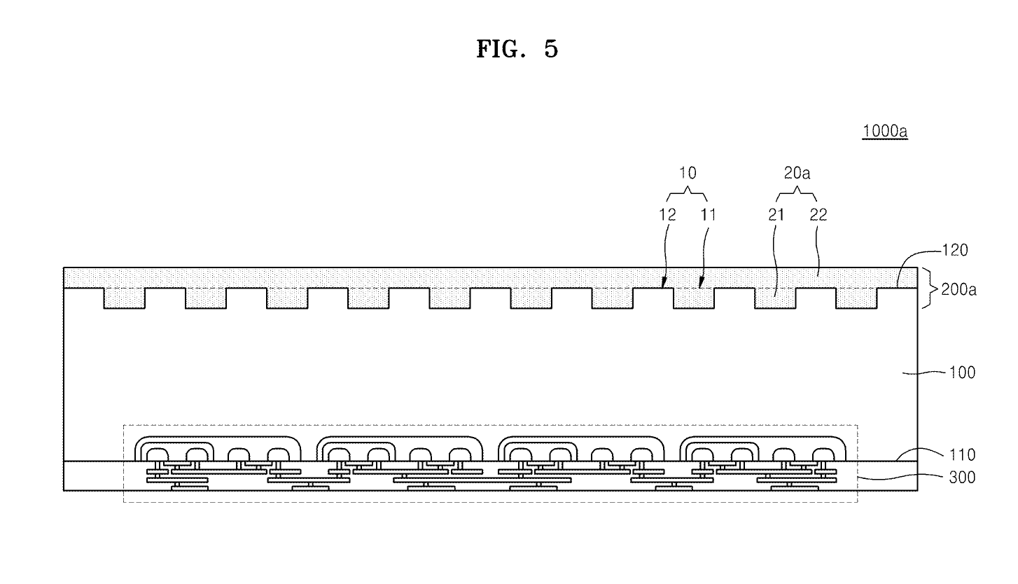

FIG. 5 is a longitudinal cross-sectional view of a semiconductor chip 1000a according to another example embodiment. Referring to FIG. 5, the semiconductor chip 1000a according to the present embodiment of the inventive concepts includes an IC 300 formed on a first surface 110 of a semiconductor substrate 100 and a heat radiation portion 200a formed on a second surface 120 of the semiconductor substrate 100 that faces the first surface 110. The semiconductor chip 1000a of FIG. 5 is different from the semiconductor chip 1000 of FIG. 1 by the structure of the heat radiation portion 200a.

The heat radiation portion 200a is formed on the second surface 120 of the semiconductor substrate 100. The heat radiation portion 200a may be formed on the whole of the second surface 120 of the semiconductor substrate 100 and may be formed after a backwrap process of the semiconductor wafer has been performed, as described above with reference to FIG. 1.

The heat radiation portion 200a may include heat radiation patterns 10 that are formed by a recess 11 and a protrusion 12, and a heat radiation layer 20a. The heat radiation patterns 10 have a heat radiation structure that is formed by a plurality of recesses 11 and a plurality of protrusions 12. The plurality of recesses 11 are formed on the second surface 120 of the semiconductor substrate 100 and are spaced apart from one another by given (or alternatively, predetermined) distances so that a plurality of protrusions 12 may be formed between the plurality of recesses 11. The plurality of recesses 11 and the plurality of protrusions 12 may be spaced apart from one another by given (or alternatively, predetermined) distances. The heat radiation patterns 10 are formed on the second surface 120 of the semiconductor substrate 100 by the plurality of recesses 11 and the plurality of protrusions 12. In this case, the heat radiation patterns 10 may be substantially the same as the heat radiation patterns 10 of the heat radiation portion 200 of the semiconductor chip 1000 of FIG. 1. Thus, the heat radiation patterns 10 may be formed as illustrated in FIGS. 3A through 3M.

The heat radiation layer 20 may include a plurality of burying portions 21 that are formed by burying a heat radiation material in the recesses 11, and an exposure portion 22 formed on an upper portion of each of the heat radiation patterns 10. The heat radiation material is applied onto the entire area of the heat radiation patterns 10 so that the burying portions 12 may be formed by burying the heat radiation material in the recesses 11 and the exposure portion 22 may be formed on an upper portion of each of the protrusions 12. Thus, the thickness of the heat radiation layer 20 may be larger than the thickness of the heat radiation patterns 10.

The heat radiation portion 200a of the semiconductor chip 1000a of FIG. 5 includes the burying portions 21 and the exposure portion 22 so that heat generated in the semiconductor chip 1000 may be transferred to the heat radiation portion 200a via the recesses 11 and the protrusions 12. Thus, heat generated in the IC 300 may be quickly transferred to the heat radiation portion 200a and the heat radiation portion 200a may dissipate heat to the external environment.

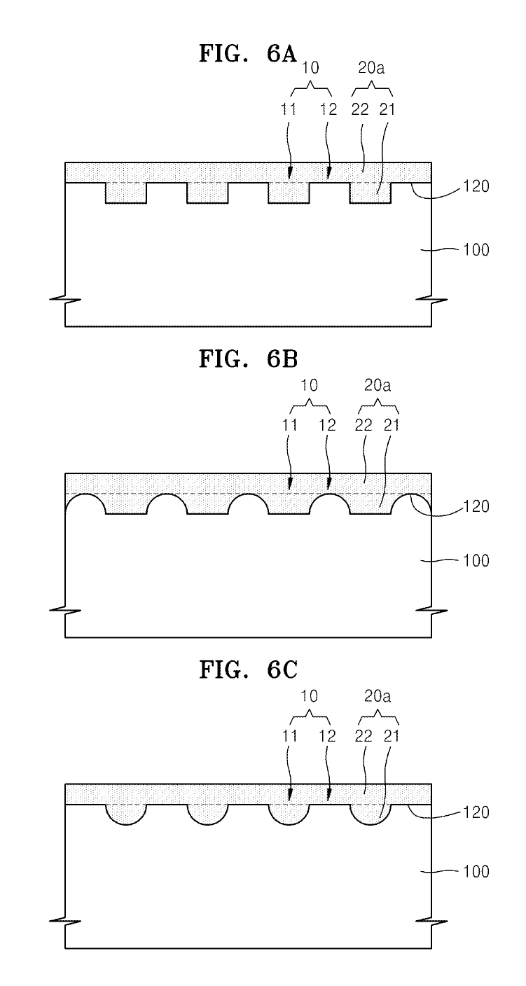

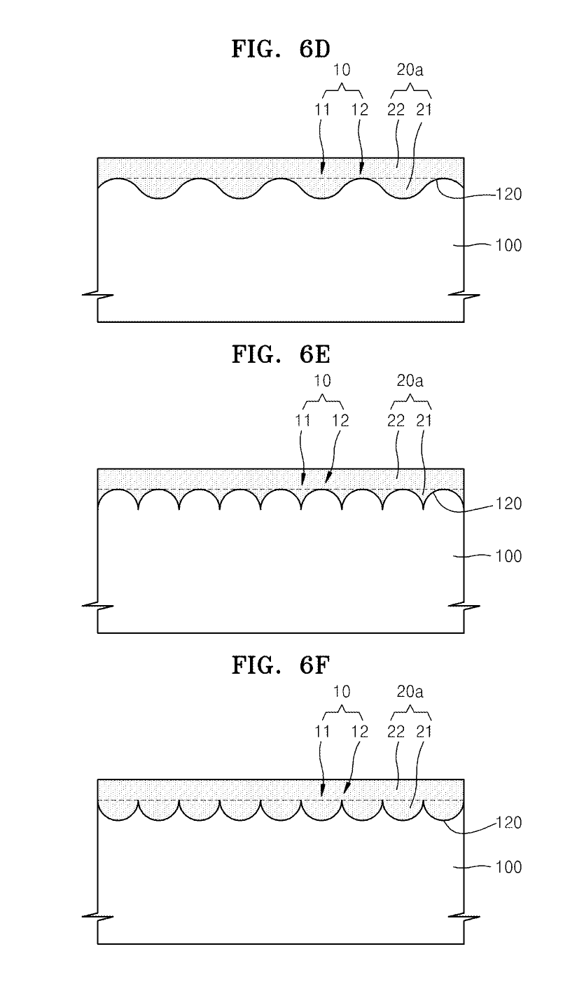

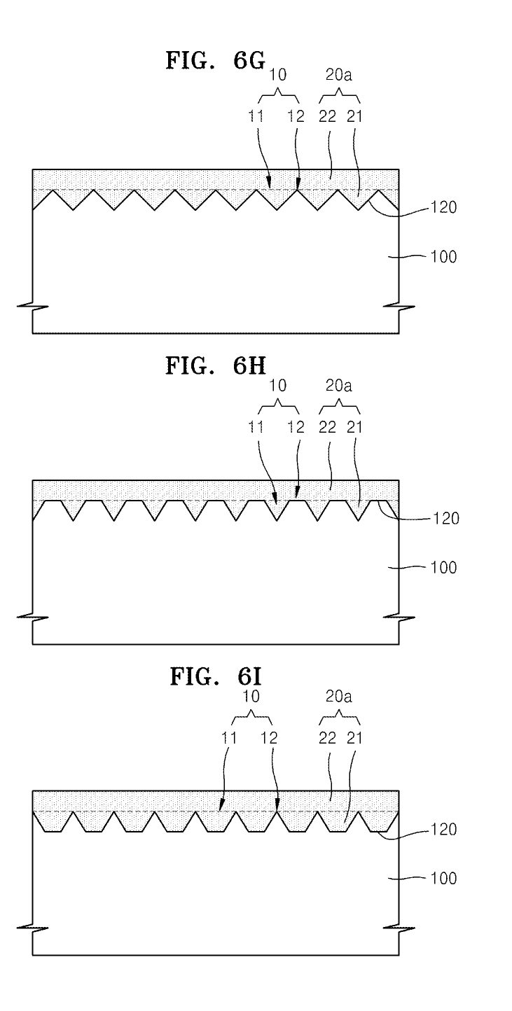

FIGS. 6A through 6I are longitudinal cross-sectional views of the heat radiation portion 200a of the semiconductor chip 1000a illustrated in FIG. 5. For conveniences of explanation, the longitudinal cross-section of the semiconductor chip 1000a including the heat radiation portion 200a is enlarged.

The shape of a cross-section of the heat radiation patterns 10 of the heat radiation portion 200a of FIGS. 6A through 6I is similar to that of FIGS. 4A through 4F. As described above with reference to FIGS. 4A through 4I, a bottom end of the recess 11 may be straight or hemispherical, and the recess 11 may be semicircular cross-section, an inverted triangular cross-section, or an inverted trapezoidal cross-section. In addition, a top end of the protrusion 12 may be straight or hemispherical, and a cross-section of the protrusion 12 may be semicircular, triangular, or trapezoidal. In one example embodiment, the thickness of the heat radiation patterns 10 may be smaller than the thickness of the heat radiation patterns 10 of the heat radiation portion 200 of FIGS. 4A through 4I.

In other words, a height of the protrusion 12 of the heat radiation portion 200a of FIGS. 6A through 6I may be smaller than a height of the protrusion 12 of the heat radiation portion 200 of FIGS. 4A through 4F. The thickness of the protrusion 12 and the thickness of the exposure portion 22 formed on the upper portion of the protrusion 12 and on the upper portion of each of the burying portions 21 may be the same as a difference between the thickness of the heat radiation patterns 10 of FIGS. 4A through 4I and the thickness of the heat radiation patterns 10 of FIGS. 6A through 6I. In addition, the shape of the cross-section of the heat radiation patterns 10 has been described with reference to FIGS. 4A through 4I and thus detailed descriptions thereof will be omitted.

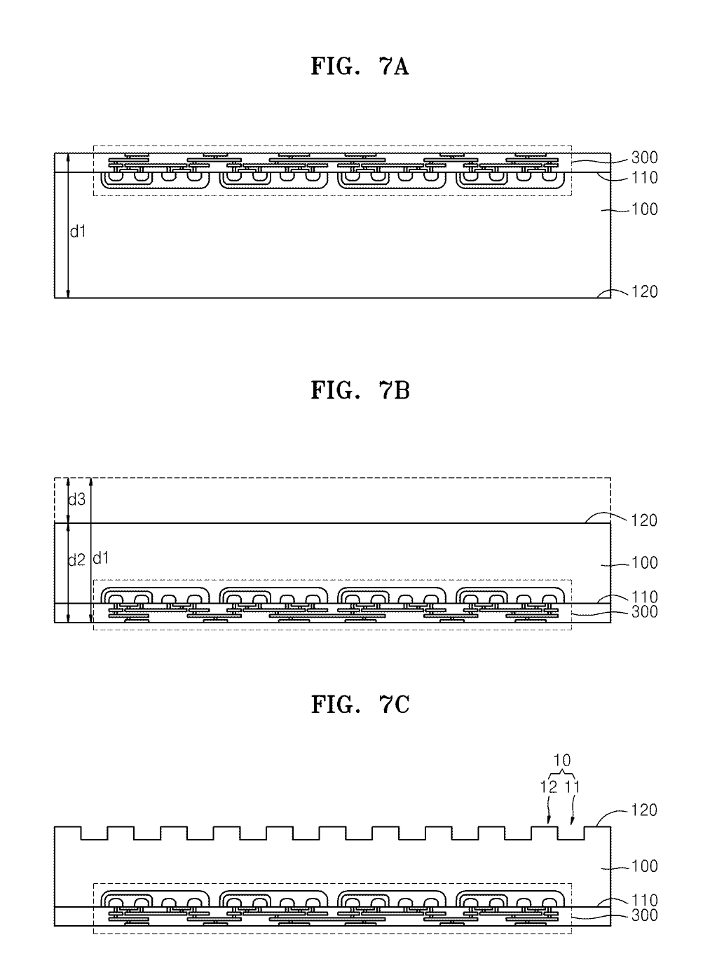

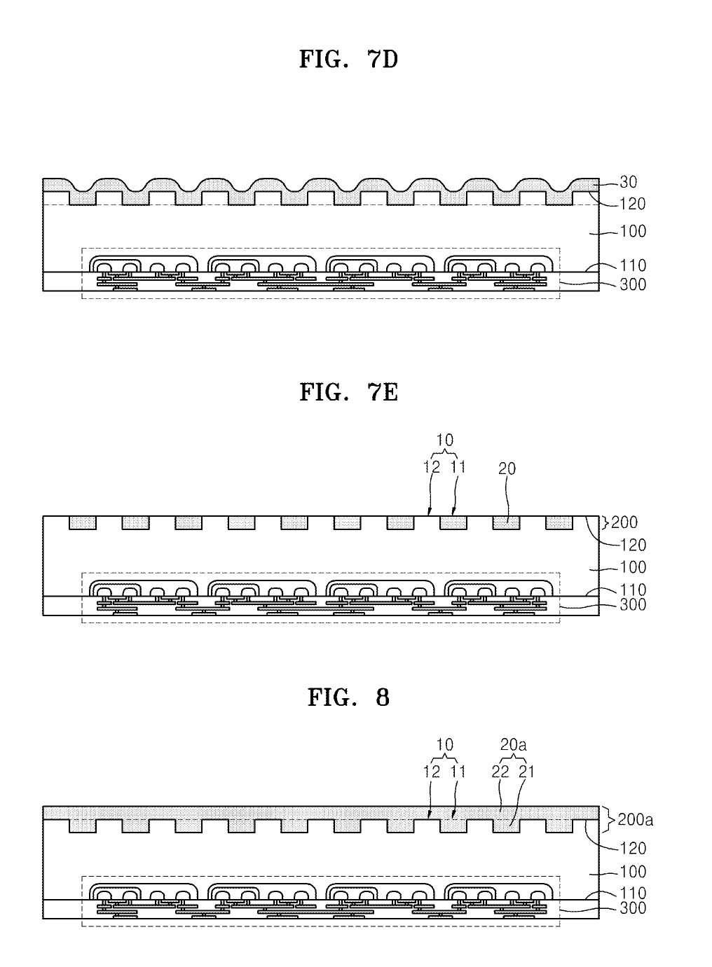

FIGS. 7A through 7F and FIG. 8 illustrate a method of fabricating a semiconductor chip according to an example embodiment.

FIG. 7A illustrates the case that the IC 300 is formed on one surface of the semiconductor substrate 100. The semiconductor substrate 100 is a semiconductor wafer and includes a first substrate 110 and a second surface 120 that faces the first surface 110. The IC 300 may be formed by patterning semiconductor devices or wirings on one surface, for example, the first surface 110 of the semiconductor substrate 100.

Referring to FIG. 7B, after the IC 300 is formed, the second surface 120, which faces the first surface 110 on which the IC 300 is formed, is polished by performing a backwrap process.

A thickness d1 of the semiconductor substrate 100 before the backwrap process is performed, i.e., the thickness d1 of a wafer, may be about several hundreds of μm. For example, the thickness of a silicon wafer having a diameter of 20 to 30 cm may be about 750 μm. However, in order to stack a semiconductor chip or to increase a packaging density, the thickness of the semiconductor chip may be reduced to be less than several tens of μm. Thus, after the IC 300 is formed on the first surface 110 of the semiconductor substrate 100, the second surface 120 is polished so as to remove a portion of the semiconductor substrate 100 having a given (or alternatively, predetermined) thickness d3. Thus, the thickness d1 of the semiconductor substrate 100 may be reduced to a thickness d2, i.e., to be less than several tens of μm.

In detail, the backwrap process may be performed by using a method, such as polishing using a diamond wheel by injecting a slurry into a wafer, chemical mechanical polishing (CMP), dry polishing using a silica adhesive pad, wet etching using chemical medicines, or using plasma.

Referring to FIG. 7C, the heat radiation patterns 10 are formed on the second surface 120 of the semiconductor substrate 100. Grooves (not shown) may be formed in the second surface 120 at regular intervals so that the heat radiation patterns 10 including a plurality of recesses 11 and a plurality of protrusions 120 may be formed.

The heat radiation patterns 10 may be formed by performing a photolithography process. For example, the protrusions 12 may be formed by forming a photomask by using silicon dioxide (SiO₂), and the recesses 11 may be formed by performing wet etching by using a potassium hydroxide (KOH) aqueous solution. In this case, the heat radiation patterns 10 may be etched at a low temperature less than 100° C. not to damage the IC 300 in the etching process. The above-described photolithography process is just an embodiment in which the heat radiation patterns 10 are formed, and a process of forming the heat radiation patterns 10 is not limited thereto. The heat radiation patterns 10 may be formed using a blade or a cutting bit, or by performing a laser drilling process. In addition, the heat radiation patterns 10 having a desired structure may be formed using various methods.

Referring to FIG. 7D, a heat radiation material 30 is applied onto upper portions of the heat radiation patterns 10. The heat radiation material 30 may be a silicon compound that is mixed with carbon or silver. The heat radiation material 30 is uniformly applied on the upper portions of the heat radiation patterns 10 at least to the same thickness as the heat radiation patterns 10.

Referring to FIG. 7E, a heat radiation layer 20 is formed by polishing the upper portions of the heat radiation patterns 10 onto which the heat radiation material 30 is unnecessarily applied in FIG. 7D, so that an upper portion of the heat radiation portion 200 may be flat. The upper portions of the heat radiation patterns 10 onto which the heat radiation material 30 is unnecessarily applied, may be removed by performing a CMP process, or the like.

Referring to FIG. 7E, a portion onto which the heat radiation material 30 is applied to more than a height of a longitudinal section of the protrusion 12, among an upper portion of the protrusion 12 onto which the heat radiation material 30 is applied and a portion of the recess 11 onto which the heat radiation material 30 is applied, as illustrated in FIG. 7D, is removed so as to form the heat radiation layer 20 by using burying portions buried in the recesses 11 and to make a top surface of the heat radiation layer 20 flat. Thus, the semiconductor chip 1000 of FIG. 1 may be fabricated.

In addition, referring to FIG. 8 that corresponds to FIG. 7E, a portion of the heat radiation material 20 applied onto the upper portion of the protrusion 12 in FIG. 7D and a portion of a portion of the protrusion 11 onto which the heat radiation material 30 is applied to a higher height than the height of the longitudinal section of the protrusion 12 in FIG. 7D are removed so as to form the heat radiation layer 20 that includes burying portions 21 and an exposure portion 22 and has a flat top surface. Thus, the semiconductor chip 1000a of FIG. 5 may be fabricated.

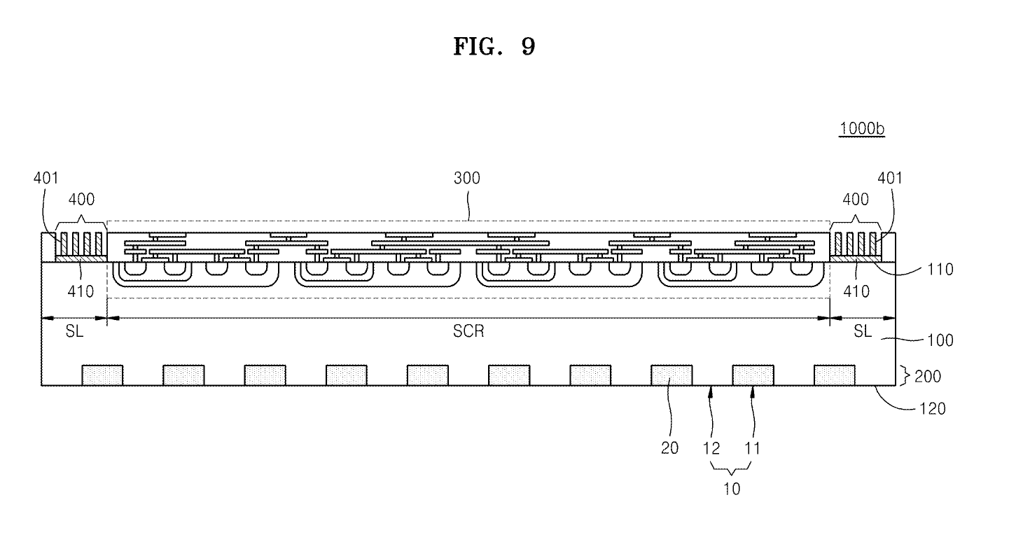

FIG. 9 is a longitudinal cross-sectional view of a semiconductor chip 1000b according to another example embodiment.

Referring to FIG. 9, the semiconductor chip 1000b according to the present embodiment includes an IC 300 and a heat radiation member 400 that are disposed on a first surface 110 of a semiconductor substrate 100, and a heat radiation portion 200 that is formed on a second surface 120 of the semiconductor substrate 100 facing the first surface 110. The heat radiation portion 200 that is formed on the second surface 120 may be substantially the same as the heat radiation portion 200 of FIG. 1 or the heat radiation portion 200a of FIG. 5. Thus, detailed descriptions thereof will be omitted.

The first surface 110 of the semiconductor substrate 100 may be divided into a circuit region SCR and a scribe lane region SL. The circuit region SCR is a region in which the IC 300 is to be formed and is located in a center of the first surface 110. The scribe lane region SL is a region in which a wafer is to be cut so as to divide a plurality of chips formed on the wafer into individual chips. Generally, the scribe lane region SL is wider than the region that is physically required to cut the wafer. Since particles may reach a portion that is close to a wafer-cut face when the wafer is cut, the width of the scribe lane region SL may be larger than an actual width required for wafer cutting, so as to prevent or inhibit particles from reaching the circuit region SCR. Thus, the scribe lane region SL includes a space that remains on the semiconductor chip 1000b even after the wafer is cut. The semiconductor chip 1000b illustrated in FIG. 9 may include a heat radiation member 400 that is disposed in the scribe lane region SL.

The heat radiation member 400 may include a plurality of heat radiation fins 401 formed of a metal having high thermal conductivity. For example, the plurality of heat radiation fins 401 may be formed of aluminum, copper, tungsten, or a mixture thereof.

The plurality of heat radiation fins 401 may extend in a direction perpendicular to the first surface 110 of the semiconductor substrate 100 and may be spaced apart from one another by given (or alternatively, predetermined) distances. In one example embodiment, the heat radiation fins 401 may be spaced apart from one another by given (or alternatively, given (or alternatively, predetermined)) distances. For example, the given (or alternatively, given (or alternatively, predetermined)) distances may be minimum distances that satisfy a minimum design rule of the method of fabricating the semiconductor chip 1000b. When more heat radiation fins 401 are formed by reducing the given (or alternatively, predetermined) distances therebetween, a heat radiation area may be increased.

The heat radiation member 400 may further include a main body portion 410. The main body portion 410 may be formed of a metal having higher thermal conductivity, like the heat radiation fins 401, may be parallel to an upper portion of the first surface 110 of the semiconductor substrate 100, and may be connected to the plurality of heat radiation fins 401.

In addition, although not shown, the heat radiation member 400 may be electrically connected to a ground voltage or a power supply voltage of the IC 300, and heat generated in the IC 300 may be quickly transferred to the heat radiation member 400.

As described above, the semiconductor chip 1000b of FIG. 9 includes the heat radiation portion 200 that is disposed on the second surface 120 of the semiconductor substrate 100 and the heat radiation member 400 that is disposed in the scribe lane region SL of the first surface 110 so that heat generated in the semiconductor chip 1000b may be dissipated via the first and second surfaces 110 and 120 of the semiconductor chip 1000b.

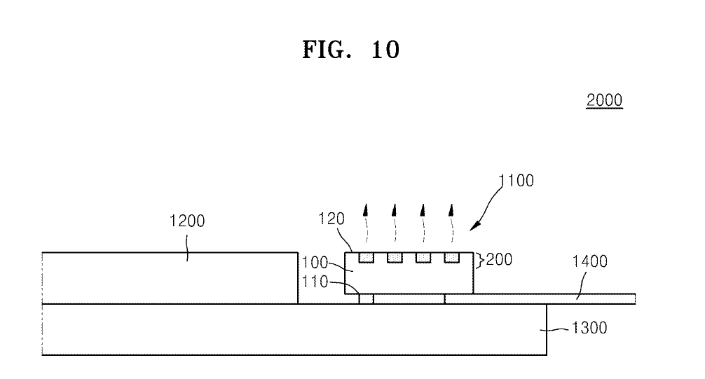

FIG. 10 is a longitudinal cross-sectional view of a display module 2000 including a display driving chip, according to an example embodiment.

Referring to FIG. 10, the display module 2000 may include a display panel 1200, a printed circuit board (PCB) 1300, and a display driving chip 1100. In addition, the display module 2000 may further include a flexible PCB (FPCB) 1400.

The display panel 1200 includes a plurality of pixels for displaying an image. In one example embodiment, the display panel 1200 may be an organic light-emitting diode panel. The display panel 1200 includes a plurality of pixels and each of the plurality of pixels includes an organic light-emitting diode that emits light in response to a flow of current. However, the inventive concepts are not limited thereto, and the display panel 1200 may be any other type of a display device. For example, the display panel 1200 may be one selected from the group consisting of a liquid crystal display (LCD) panel, an electrochromic display (ECD) panel, a digital minor device (DMD) panel, an actuated mirror device (AMD) panel, a grating light value (GLV) panel, a plasma display panel (PDP), an electro luminescent display (ELD) panel, a light emitting diode (LED) display panel, and a vacuum fluorescent display (VFD) panel.

The display driving chip 1100 generates a signal for driving the display panel 1200 and transfers the signal to the display panel 1200. The display driving chip 1100 may include a voltage generator, a data driver, a scan driver, and a timing controller. The display driving chip 1100 is a semiconductor chip including a heat radiation portion 200 that is disposed on one side of the display driving chip 1100 according to an example embodiment. In addition, the display driving chip 1100 may be a semiconductor chip that further includes a heat radiation member (see 400 of FIG. 9) in a scribe lane region.

The display driving chip 1100 is mounted on the PCB 1300. Wirings are disposed on the PCB 1300 so as to electrically connect the display driving chip 1100 and the display panel 1200. Thus, by electrically connecting output pads of the display driving chip 1100 and the display panel 1200, the driving signal output from the display driving chip 1100 is transmitted to the display panel 1200. In one embodiment, the PCB 1300 may be the same as a lower substrate of the display panel 1200. For example, the PCB 1300 may be a glass substrate that is the lower substrate of the display panel 1200, and the wirings for electrically connecting the display driving chip 1200 and the display driving chip 1100 may be indium tin oxide (ITO) wirings.

The FPCB 1400 is connected to input pads of the display driving chip 1100. Wirings are formed on the FPCB 1400 so as to apply an input signal from an application processor (not shown) or the like to the input pads of the display driving chip 1100.

As illustrated in FIG. 10, when the display driving chip 1100 is mounted on the PCB 1300, a first surface 110 of the semiconductor substrate 100 is a bottom surface, and a second surface 120 of the semiconductor substrate 100 is a top surface. Input/output pads of the display driving chip 1100 are formed in a circuit region of the first surface 110. Since the display driving chip 1100 illustrated in FIG. 10 includes the heat radiation portion 200 formed on the entire area of the second surface 120, heat generated in the display driving chip 1100 may be dissipated via the heat radiation portion 200 formed on the second surface 120.

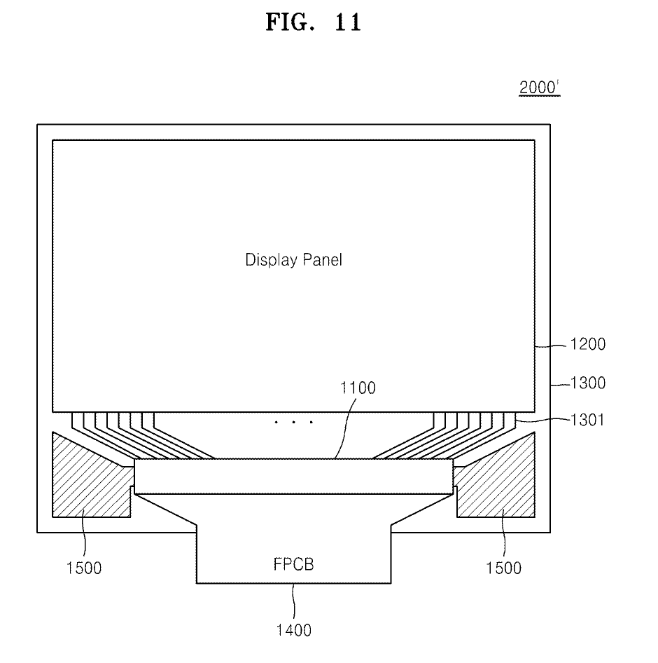

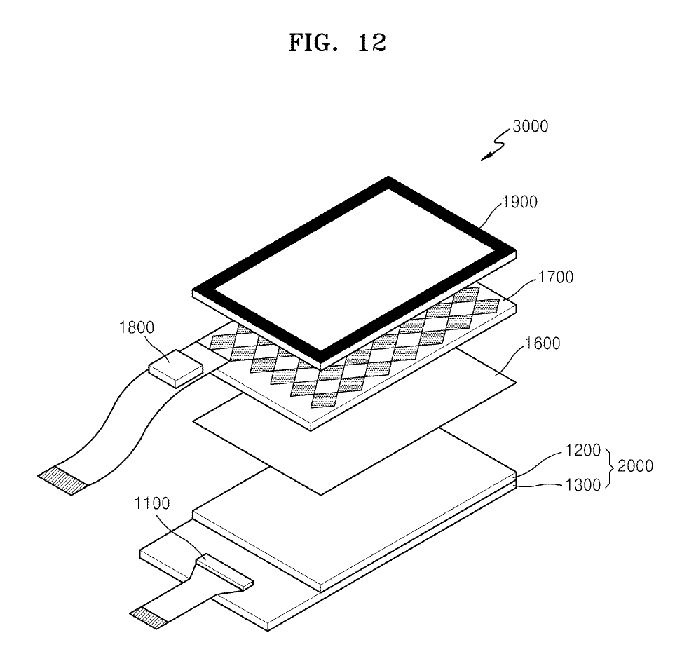

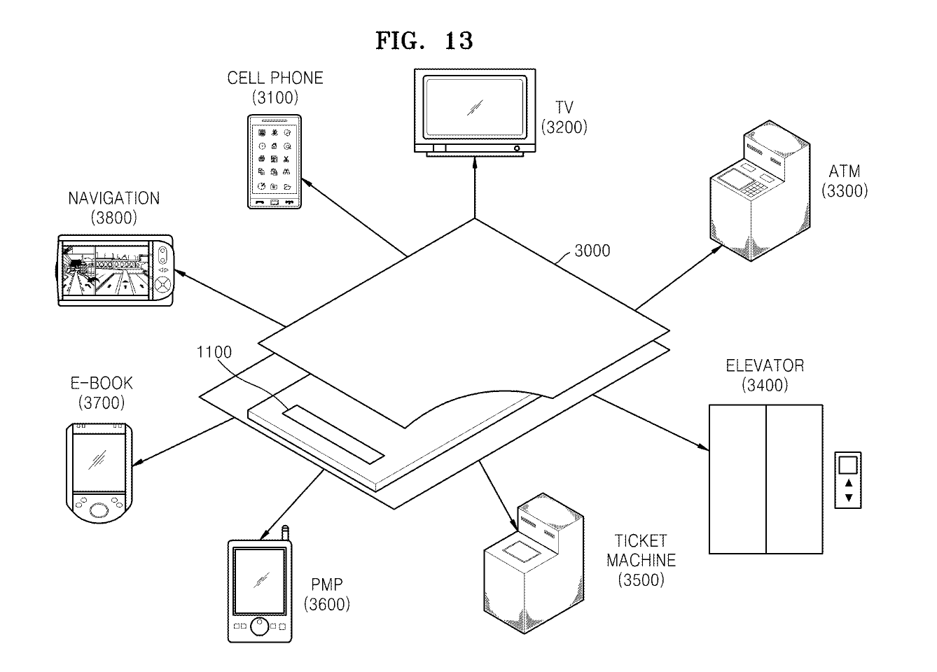

FIG. 11 is a plan view of a display module 2000′ according to another example embodiment. Referring to FIG. 11, the display module 2000′ may include a display panel 1200, a PCB 1300, and a display driving chip 1100. In addition, the display module 2000′ may further include an FPCB 1400.

The display module 2000′ is similar to the display module 2000 of FIG. 9. However, the PCB 1300 of the display module 2000′ of FIG. 11 may further include a heat radiation plate 1500.

As illustrated in FIG. 11, a display driving chip 1100 is mounted on the PCB 1300, wirings 1301 for electrically connecting output pads of the display driving chip 1100 and the display panel 1200 are formed over a top end of the display driving chip 1100, and the FPCB 1400 is disposed under a bottom end of the display driving chip 1100 and is connected to input pads of the display driving chip 1100.

In this case, the heat radiation plate 1500 formed of metal may be disposed on both side surfaces of the display driving chip 1100 on the PCB 1300. For example, the heat radiation plate 1500 may be formed of tungsten, copper, gold, silver, aluminum, or a compound material thereof. As illustrated in FIG. 11, side surfaces of the heat radiation plate 1500 may contact side surfaces of the display driving chip 1100, or the heat radiation plate 1500 may be connected to the input pads for supplying a ground voltage or a power voltage to the display driving chip 1100. Thus, heat generated in the display driving chip 1100 may be dissipated to the heat radiation plate 1500.

In the present embodiment, the display module 2000′ including a single display driving chip 1100 for driving the display panel 1200 has been described; however, the inventive concepts are not limited thereto. Thus, the display module 2000′ may include a plurality of display driving chips 1100 and the heat radiation plate 1500 disposed on both side surfaces of the plurality of display driving chip 1100 on the PCB 1300.

FIG. 12 illustrates a structure of a display device 3000 according to an example embodiment. Referring to FIG. 12, the display device 3000 according to the present embodiment may include a PCB 1300, a display driving chip 1100, a display panel 1200, a polarization plate 1600, and a window glass 1900.

The window glass 1900 may be generally formed of acryl or tempered glass and may protect a display module 2000 from an external shock or scratch due to repetitive touch operations. The polarization plate 1600 may be disposed so as to improve the optical characteristics of the display panel 1200. The display panel 1200 is formed by patterning transparent electrodes on the PCB 1300.

The display driving chip 1100 may be a semiconductor chip (see 1000 of FIG. 1, 1000a of FIGS. 5, and 1000b of FIG. 9) according to example embodiments. Thus, the display driving chip 1100 includes a heat radiation portion so as to effectively dissipate generated heat. The display driving chip 1100 in a form of a chip on glass (COG) may be mounted on the PCB 1300. However, this is just an example, and the display driving chip 1100 may be mounted in various forms, such as a chip on film (COF), a chip on board (COB), and the like.

The display device 3000 may further include a touch panel 1700 and a touch controller 1800. The touch panel 1700 may be formed by patterning transparent electrodes, such as indium tin oxide (ITO) electrodes, on a glass substrate or a polyethylene terephthalate (PET) film. The touch controller 1800 senses a touch on the touch panel 1700, calculates a touch coordinate, and transfers the touch coordinate to a host (not shown). The touch controller 1800 may be integrated in the display driving chip 1100.

FIG. 13 illustrates examples of various electronic products including a display device, according to an example embodiment.

The display device 3000 according to the inventive concepts may be employed in various electronic products. Thus, the display device 300 may be employed in a television (TV) 3200, an automated teller machine (ATM) 3300, an elevator 3400, a ticket machine 3500 used in a subway station or the like, a portable multimedia player (PMP) 3600, an e-book 3700, a navigation device 3800, as well as a cell phone 3100.

While the inventive concepts have been particularly shown and described with reference to example embodiments thereof, it will be understood that various changes in form and details may be made therein without departing from the spirit and scope of the following claims.

1. A semiconductor chip comprising:
a semiconductor substrate including a first surface and a second surface;
an integrated circuit (IC) on the first surface of the semiconductor substrate; and
a heat radiation portion on the second surface of the semiconductor substrate, the heat radiation portion including,
heat radiation patterns in a direction perpendicular to the second surface, the heat radiation patterns including a plurality of recesses and a plurality of protrusions, and
a heat radiation layer on upper portions of the heat radiation patterns, the heat radiation layer including a metal material and having a flat upper surface.

2. The semiconductor chip of claim 1, wherein the heat radiation layer includes burying portions in the plurality of recesses, the burying portions including the metal material.

3. The semiconductor chip of claim 1, wherein the heat radiation layer comprises:
burying portions in the plurality of recesses, the burying portions including the metal material; and
an exposure portion on an upper portion of each of the burying portions and an upper portion of each of the plurality of protrusions.

4. The semiconductor chip of claim 1, wherein the heat radiation patterns include stripe patterns on the second surface, the stripe patterns including the plurality of protrusions having straight line shapes extending in a first direction, the plurality of protrusions being formed along a second direction perpendicular to the first direction and spaced apart from one another.

5. The semiconductor chip of claim 1, wherein the heat radiation patterns include lattice patterns on the second surface, the lattice patterns including one of the plurality of protrusions and the plurality of recesses having rectangular shapes formed in a first direction and in a second direction perpendicular to the first direction and spaced apart from one another.

6. The semiconductor chip of claim 1, wherein the heat radiation patterns include circular patterns on the second surface, the circular patterns including one of the plurality of protrusions and the plurality of recesses having circular shapes formed in a first direction and in a second direction perpendicular to the first direction and spaced apart from one another.

7. The semiconductor chip of claim 1, wherein the heat radiation patterns include ring-shaped patterns on the second surface, the ring-shaped patterns including one of the plurality of protrusions and the plurality of recesses having ring shapes formed in a first direction and in a second direction perpendicular to the first direction and spaced apart from one another.

8. The semiconductor chip of claim 1, wherein one of a top end of a longitudinal cross-section of each of the plurality of protrusions and a bottom end of a longitudinal cross-section of each of the plurality of recesses is straight.

9. The semiconductor chip of claim 1, wherein one of a top end of a longitudinal cross-section of each of the plurality of protrusions and a bottom end of a longitudinal cross-section of each of the plurality of recesses is round.

10. The semiconductor chip of claim 1, wherein each of the plurality of recesses has one of an inverted triangular cross-section and an inverted trapezoidal cross-section.

11. The semiconductor chip of claim 1, wherein the metal material includes a silicon compound including one of carbon and silver.

12. The semiconductor chip of claim 1, wherein the IC includes a driving circuit configured to drive a display panel.

13.-15. (canceled)

16. A semiconductor chip comprising:
a semiconductor substrate including a first surface and a second surface;
an integrated circuit (IC) on the first surface of the semiconductor substrate; and
a heat radiation portion on the second surface of the semiconductor substrate, the heat radiation portion including a plurality of recesses and a metal material in the plurality of recesses.

17. The semiconductor chip of claim 16, wherein the heat radiation portion has a flat upper surface.

18. The semiconductor chip of claim 16, wherein the heat radiation portion further comprises a plurality of protrusions separated by the plurality of recesses.

19. The semiconductor chip of claim 18, wherein one of a top end of a longitudinal cross-section of each of the plurality of protrusions and a bottom end of a longitudinal cross-section of each of the plurality of recesses is one of straight and round.

20. The semiconductor chip of claim 18, wherein the plurality of protrusions have straight line shapes extending in a first direction and formed along a second direction perpendicular to the first direction.

21. The semiconductor chip of claim 18, wherein at least one of the plurality of protrusions and the plurality of recesses have one of circular, ring and rectangular shapes formed in a first direction and in a second direction perpendicular to the first direction.

22. The semiconductor chip of claim 16, wherein each of the plurality of recesses has one of an inverted triangular cross-section and an inverted trapezoidal cross-section.

23. The semiconductor chip of claim 16, wherein the metal material includes a silicon compound including one of carbon and silver.
